(19) United States
(12) Patent Application Publication
(10) Pub. No.: US 2014/0183590 A1
(43) Pub. Date: Jul. 3, 2014

(54) NITRIDE SEMICONDUCTOR LIGHT EMITTING DEVICE AND METHOD OF MANUFACTURING THE SAME

(71) Applicant: ILJIN LED CO., LTD., Ansan-si (KR)

(72) Inventors: Seung-Yong KIM, Ansan-si (KR); Jeong-Woo HONG, Incheon (KR)

(73) Assignee: ILJIN LED CO., LTD., Ansan-si (KR)

(21) Appl. No.: 14/136,433

(22) Filed: Dec. 20, 2013

(30) Foreign Application Priority Data
Dec. 28, 2012 (KR) 10-2012-0156369

(51) Int. Cl. H01L 33/38; H01L 33/44; H01L 33/42

(52) U.S. Cl. CPC H01L 33/38; H01L 33/42; H01L 33/44
USPC 257/99; 438/39

(57) ABSTRACT

A nitride semiconductor light emitting device and a method of manufacturing the same are disclosed. The nitride semiconductor light emitting device includes an n-type nitride layer; an active layer formed on the n-type nitride layer; a p-type nitride layer formed on the active layer; a current blocking pattern formed on the p-type nitride layer; a transparent conductive pattern formed to cover upper sides of the p-type nitride layer and the current blocking pattern, and having a contact hole through which a portion of the current blocking pattern is exposed; and a p-electrode pad formed on the current blocking pattern and the transparent conductive pattern, and directly connected to the current blocking pattern. The nitride semiconductor light emitting device can improve long term durability by securing excellent light scattering properties while enhancing adhesion of a p-electrode pad.

### CROSS-REFERENCE TO RELATED APPLICATION

This application claims priority to Korean Patent Application No. 10-2012-0156369 filed on Dec. 28, 2013, and all the benefits accruing therefrom under 35 U.S.C. §119, the contents of which is incorporated by reference in its entirety.

### BACKGROUND

1. Technical Field

The present invention relates to a semiconductor light emitting device and a method of manufacturing the same. More particularly, the present invention relates to a nitride semiconductor light emitting device which has excellent light scattering capabilities and adhesion, and a method of manufacturing the same.

2. Description of the Related Art

In recent years, gallium nitride (GaN)-based nitride semiconductor light emitting devices have been mainly studied as nitride semiconductor light emitting devices. Such a GaN-based nitride semiconductor light emitting device is used in various applications, including blue and green light emitting diodes (LEDs), high speed and high output devices, such as MESFETs, HEMTs, and the like.

In order to improve optical efficiency, a nitride semiconductor light emitting device is formed with a current blocking layer under an area in which a p-type metal electrode is placed, and a transparent conductive pattern on the current blocking layer. Here, the transparent conductive pattern acts as an electrode of a p-electrode pad and a current spreading layer.

However, in the nitride semiconductor light emitting device having such a structure, the transparent conductive pattern is formed on the current blocking pattern formed of an insulating material. In this case, since the transparent conductive pattern and the p-electrode pad are formed of metallic materials, there is a problem in rapid deterioration in bonding reliability due to insufficient adhesion therebetween.

Korean Patent No. 10-0793337 (issued on Jan. 11, 2008) discloses a nitride semiconductor light emitting device and a method of manufacturing the same.

### BRIEF SUMMARY

Therefore, the present invention is aimed at providing a nitride semiconductor light emitting device which can improve long term durability by securing excellent light scattering capabilities while enhancing adhesion of a p-electrode pad, and a method of manufacturing the same.

In accordance with one aspect of the present invention, a nitride semiconductor light emitting device includes an n-type nitride layer; an active layer formed on the n-type nitride layer; a p-type nitride layer formed on the active layer; a current blocking pattern formed on the p-type nitride layer; a transparent conductive pattern formed to cover upper sides of the p-type nitride layer and the current blocking pattern, and having a contact hole through which a portion of the current blocking pattern is exposed; and a p-electrode pad formed on the current blocking pattern and the transparent conductive pattern, and directly connected to the current blocking pattern.

In accordance with another aspect of the present invention, a method of manufacturing a nitride semiconductor light emitting device includes: (a) sequentially forming an n-type nitride layer, an active layer and a p-type nitride layer on a substrate; (b) forming a current blocking pattern on the p-type nitride layer; (c) forming a transparent conductive layer to cover upper sides of the p-type nitride layer and the current blocking pattern, followed by primary patterning a portion of the transparent conductive layer placed at one edge of the substrate; (d) mesa-etching the p-type nitride layer, the active layer and the n-type nitride layer exposed at the one edge of the substrate to expose a portion of the n-type nitride layer; (e) secondary patterning the transparent conductive layer to form a transparent conductive pattern having a contact hole through which a portion of the current blocking pattern is exposed; and (f) forming a p-electrode pad directly connected to the current blocking pattern, and an n-electrode pad on the exposed portion of the n-type nitride layer.

In the light emitting device according to the present invention, the current blocking pattern is formed on the p-type nitride layer, the transparent conductive pattern having a contact hole is formed on the p-type nitride layer and the current blocking pattern to improve light scattering capabilities, and the p-electrode pad is electrically and physically directly connected to the current blocking pattern formed of an insulating material via the transparent conductive pattern having the contact hole to improve adhesion of the p-electrode pad, thereby enhancing long-term reliability.

### BRIEF DESCRIPTION OF THE DRAWINGS

The above and other aspects, features, and advantages of the invention will become apparent from the detailed description of the following embodiments in conjunction with the accompanying drawings, in which:

FIG. 1 is a sectional view of a nitride semiconductor light emitting device according to one embodiment of the present invention;

FIG. 2 is a partially enlarged view of part A in FIG. 1;

FIG. 3 is a flowchart of a method of manufacturing a nitride semiconductor light emitting device according to one embodiment of the present invention; and

FIGS. 4 to 10 are sectional views illustrating the method of manufacturing a nitride semiconductor light emitting device according to the embodiment of the present invention.

### DETAILED DESCRIPTION

Exemplary embodiments of the present invention will now be described in detail with reference to the accompanying drawings.

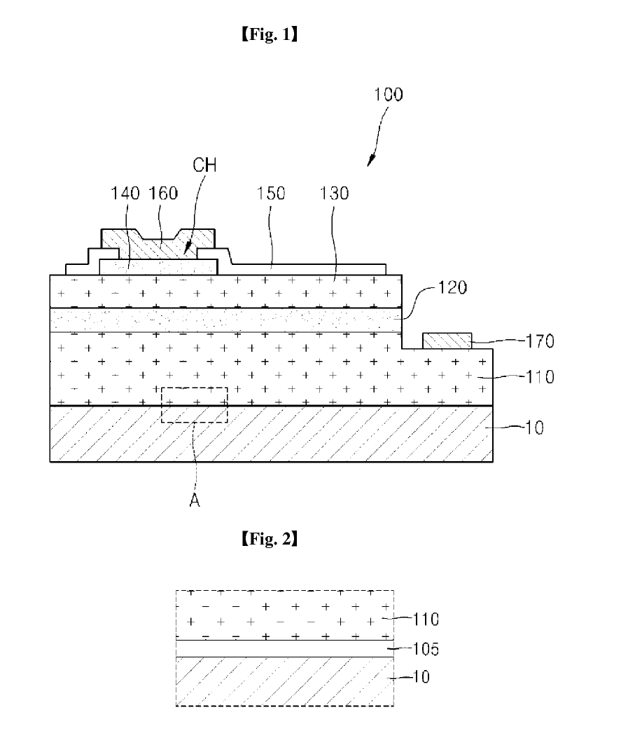

FIG. 1 is a sectional view of a nitride semiconductor light emitting device according to one embodiment of the present invention and FIG. 2 is a partially enlarged view of part A in FIG. 1.

Referring to FIGS. 1 and 2, a nitride semiconductor light emitting device 100 according to one embodiment of the invention includes an n-type nitride layer 110, an active layer 120, a p-type nitride layer 130, a current blocking pattern 140, a transparent conductive pattern 150, a p-electrode pad 160, and an n-electrode pad 170. The nitride semiconductor light emitting device 100 may further include a buffer layer 105.

The n-type nitride layer 110 is formed on a substrate 10 or on the buffer layer 105. The n-type nitride layer 110 may have a stack structure in which first silicon (Si)-doped AlGaN layers (not shown) and second undoped GaN layers are alternately stacked one above another. Although the n-type nitride layer may be formed by growing a single nitride layer, it is desirable that the n-type nitride layer be formed in the stack structure including the buffer layer 105 and the first and second layers alternately stacked one above another to secure excellent crystallinity without forming cracks.

Here, the substrate 10 may be formed of a material suitable for growth of a single crystal nitride semiconductor. For example, the substrate 10 may be a sapphire substrate. In addition, the substrate 10 may be formed of a material selected from zinc oxide (ZnO), gallium nitride (GaN), silicon (Si), silicon carbide (SiC), aluminum nitride (AlN), and the like. Further, the buffer layer 105 is optionally formed on an upper surface of the substrate 10 to relieve lattice mismatch between the substrate 10 and the n-type nitride layer 110. The buffer layer 105 may be formed of AlN, GaN, and the like.

The active layer 120 is formed on the n-type nitride layer 110. The active layer 120 is formed between the n-type nitride layer 110 and the p-type nitride layer 130, and may have a single quantum well structure, or a multi-quantum well (MQW) structure in which quantum well layers and quantum barrier layers are alternately stacked. Specifically, the active layer 120 may have a multi-quantum well structure which includes quantum barrier layers formed of quaternary nitride layers of AlGaInN and quantum well layers of InGaN. The active layer 120 having such a multi-quantum well structure can suppress spontaneous polarization by stress and deformation.

The p-type nitride layer 130 may have, for example, a stack structure formed by alternately stacking a first p-type layer (not shown) composed of p-type AlGaN doped with Mg and a second p-type layer (not shown) composed of p-type GaN doped with Mg. In addition, the p-type nitride layer 130 may act as a carrier restriction layer like the n-type nitride layer 110.

The current blocking pattern 140 is formed on the p-type nitride layer 130. Such a current blocking pattern 140 is formed at a place corresponding to an area (not shown) in which a p-electrode pad described below will be formed.

The current blocking pattern 140 serves to compensate for optical loss due to photon absorption at a lower surface corresponding to the p-electrode pad 160. Further, the current blocking pattern 140 prevents current crowding near the p-electrode pad 160 due to low conductivity of the p-electrode pad 160 having a lower thickness than the n-type nitride layer 110.

Such a current blocking pattern 140 is preferably formed of at least one selected from SiO₂, SiNx, and the like. The current blocking pattern 140 preferably has a thickness of 0.01 μm to 0.50 μm, more preferably 0.1 μm to 0.3 μm. When the thickness of the current blocking pattern 140 is less than 0.01 μm, there can be difficulty in realization of the current blocking function. Conversely, when the thickness of the current blocking pattern 140 exceeds 0.50 μm, there can be increase in manufacturing cost and time without significantly improving current blocking.

The transparent conductive pattern 150 is formed to cover upper sides of the p-type nitride layer 130 and the current blocking pattern 140, and has a contact hole (CH) through which a portion of the current blocking pattern 140 is exposed. Such a transparent conductive pattern 150 is formed for the purpose of increasing a current injection area, and may be formed of a transparent conductive material in order to prevent undesirable influence on brightness. Specifically, the transparent conductive pattern 150 may be formed of at least one selected from among indium tin oxide (ITO), indium zinc oxide (IZO), fluorine-doped tin oxide (SnO₂) (FTO), and the like.

The p-electrode pad 160 is formed on the current blocking pattern 140 and the transparent conductive pattern 150, and is directly connected to the current blocking pattern 140. In plan view, the p-electrode pad 160 may have a first area and the current blocking pattern 140 has a second area larger than or equal to the first area. This is because the larger area of the current blocking pattern 140 than that of the p-electrode pad 160 is advantageous in compensation for optical loss due to photon absorption. Namely, it is desirable that the overall area of the p-electrode pad 160 overlap the current blocking pattern 140 in plan view. The larger area of the current blocking pattern 140 than that of the p-electrode pad 160 can improve light scattering characteristics.

Particularly, the p-electrode pad 160 is electrically and physically directly connected to the current blocking pattern 140. In this way, since the p-electrode pad 160 is directly connected to the current blocking pattern 140 via the contact hole (CH) of the transparent conductive pattern 150, the p-electrode pad 160 has a T-shaped cross-section formed by a step near the contact hole (CH). Here, since the p-electrode pad 160 and the transparent conductive pattern 150 are formed of metallic materials, there can be a problem of poor adhesion therebetween. However, in the present invention, the p-electrode pad 160 is electrically and physically directly connected to the current blocking pattern 140 formed of an insulating material, thereby improving adhesion of the p-electrode pad 160.

The n-electrode pad 170 is formed in an exposed area of the n-type nitride layer 110. The p-electrode pad 160 and the n-electrode pad 170 may be formed by at least one selected from among electron beam (E-Beam) deposition, thermal evaporation, sputtering, and the like. The p-electrode pad 160 and the n-electrode pad 170 are formed of the same material using the same mask. The p-electrode pad 160 and the n-electrode pad 170 may be formed of one material selected from among Au, Cr—Au alloys, and the like.

In the nitride semiconductor light emitting device according to the embodiment, the current blocking pattern is formed on the p-type nitride layer and the transparent conductive pattern having the contact hole is formed on the upper sides of the p-type nitride layer and the current blocking pattern to improve optical scattering characteristics. In addition, the p-electrode pad is electrically and physically directly connected to the current blocking pattern 140 formed of an insulating material through the contact hole of the transparent conductive pattern to improve adhesion of the p-electrode pad, thereby enhancing long-term reliability.

Next, a method of fabricating a nitride semiconductor light emitting device according to one embodiment of the invention will be described.

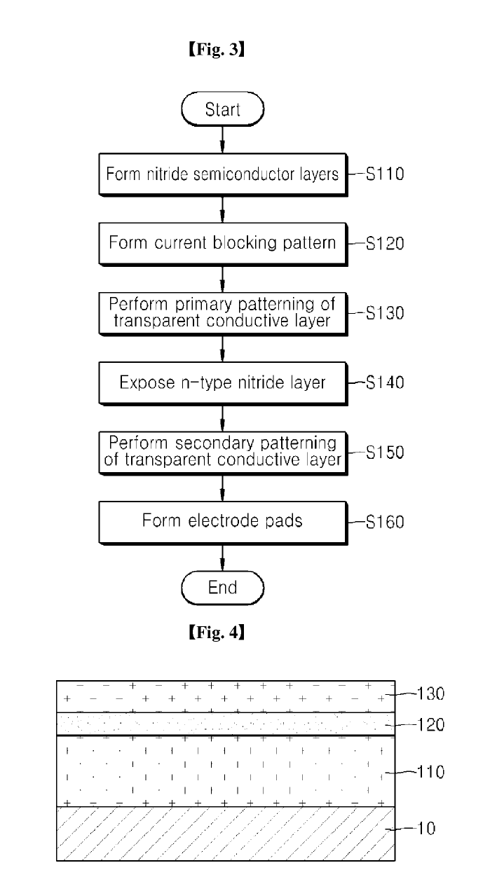

FIG. 3 is a flowchart of a method of manufacturing a nitride semiconductor light emitting device according to one embodiment of the present invention, and FIG. 4 to FIG. 10 are sectional views illustrating the method of manufacturing a nitride semiconductor light emitting device according to the embodiment of the present invention.

Referring to FIG. 3, the method of manufacturing a nitride semiconductor light emitting device includes forming nitride semiconductor layers (S110), forming a current blocking pattern (S120), performing primary patterning of a transparent conductive layer (S130), exposing an n-type nitride layer (S140), performing secondary patterning of the transparent conductive layer (S150), and forming electrode pads (S160).

Referring to FIGS. 3 and 4, in operation of forming nitride semiconductor layers (S110), an n-type nitride layer 110, an active layer 120 and a p-type nitride layer 130 are sequentially formed on a substrate 10. The n-type nitride layer 110, active layer 120 and p-type nitride layer 130 may be sequentially stacked by at least one selected from among metal organic chemical vapor deposition (MOCVD), liquid phase epitaxy (LPE), molecular beam epitaxy (MBE), and the like.

The n-type nitride layer 110 may have a stack structure in which first silicon (Si)-doped AlGaN layers (not shown) and second undoped GaN layers are alternately stacked one above another. The active layer 120 may have a single quantum well structure, or a multi-quantum well (MQW) structure in which quantum well layers and quantum barrier layers are alternately stacked one above another. In addition, the p-type nitride layer 130 may have, for example, a stack structure formed by alternately stacking a first p-type layer (not shown) composed of p-type AlGaN doped with Mg and a second p-type layer (not shown) composed of p-type GaN doped with Mg.

Although not shown in the drawings, a buffer layer (not shown) may be further formed on the substrate 10 before formation of the n-type nitride layer 110. Here, the buffer layer serves to relieve lattice mismatch between the substrate 10 and the n-type nitride layer 110, and may be formed of AlN, GaN, and the like.

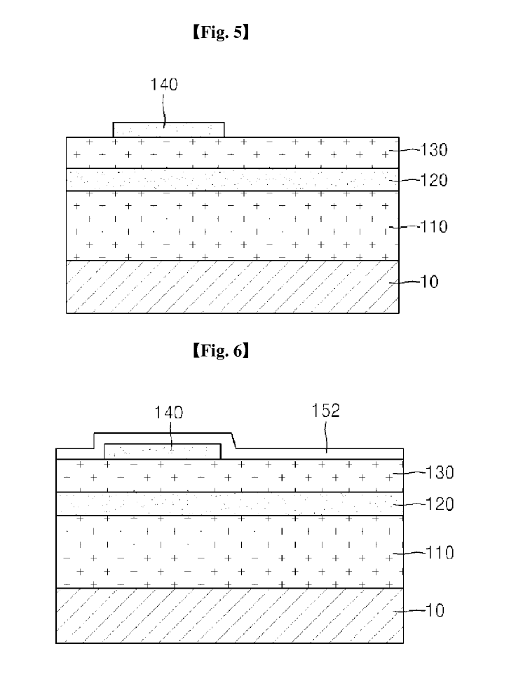

Referring to FIGS. 3 and 5, in operation of forming a current blocking pattern (S120), the current blocking pattern 140 is formed on the p-type nitride layer 130. The current blocking pattern 140 is formed at a place corresponding to an area (not shown) in which a p-electrode pad described below will be formed.

Although not shown in the drawings, the current blocking pattern 140 may be formed by depositing at least one selected from among SiO₂, SiNx, and the like to a thickness of 0.01 μm to 0.50 μm over an upper surface of the p-type nitride layer 130 to form a current blocking material layer (not shown), followed by photolithography using a first mask (not shown). Although not shown in the drawings, photolithography may be performed by depositing a photoresist material to a certain thickness over the upper sides of the p-type nitride layer 130 and the current blocking pattern 140 to form a photomask (not shown), selectively exposing and developing the photomask, selectively etching the p-type nitride layer 130 and the current blocking pattern 140 using the photomask, and removing the remaining photomask using a stripping liquid.

Here, the current blocking pattern 140 is preferably formed to a thickness of 0.01 μm to 0.50 μm. When the thickness of the current blocking pattern 140 is less than 0.01 μm, there can be difficulty in realization of the current blocking function. Conversely, when the thickness of the current blocking pattern 140 exceeds 0.50 μm, there can be increase in manufacturing cost and time without significantly improving the current blocking effect

Referring to FIGS. 3 and 6, in operation of performing primary patterning of a transparent conductive layer (S130), a transparent conductive layer 152 is formed to cover the overall upper sides of the p-type nitride layer 130 and the current blocking pattern 140, and a portion of the transparent conductive layer 152 disposed at one edge of the substrate 10 is subjected to primary patterning.

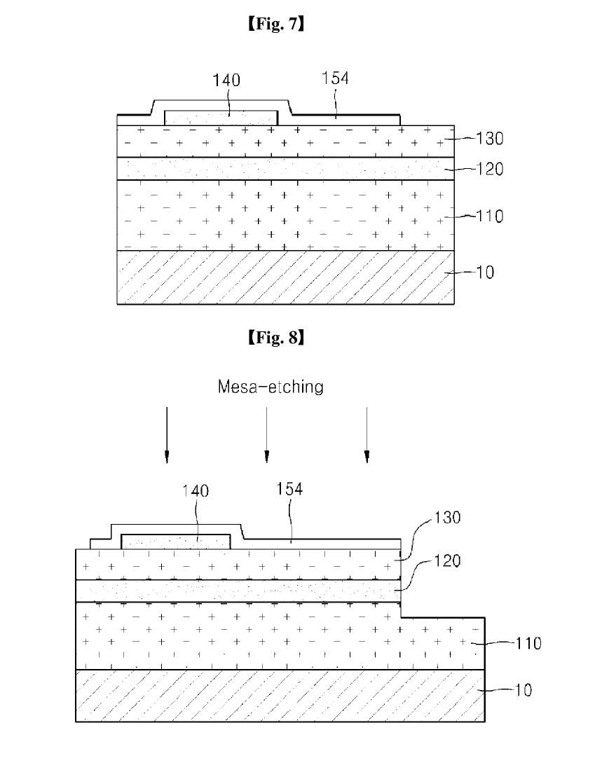

Next, referring to FIGS. 3 and 7, a preliminary transparent conductive pattern 154 is formed by primary patterning. The preliminary transparent conductive pattern 154 may be formed by photolithography using a second mask. Here, the transparent conductive layer 152 (see FIG. 6) may be formed of at least one selected from among indium tin oxide (ITO), indium zinc oxide (IZO), fluorine-doped tin oxide (SnO₂) (FTO), and the like.

Referring to FIGS. 3 and 8, in operation of exposing the n-type nitride layer (S140), exposed portions of the p-type nitride layer 130, active layer 120 and n-type nitride layer 110 at the edge of the substrate are sequentially subjected to mesa etching to expose the n-type nitride layer 110. Although not shown in the drawings, mesa etching may be performed in a way of sequentially removing the p-type nitride layer 130, the active layer 120 and the n-type nitride layer 110, which are exposed outside the preliminary transparent conductive pattern 152.

Referring to FIGS. 3 and 9, in operation of performing secondary patterning of the transparent conductive layer (S150), the transparent conductive layer, more specifically, the preliminary transparent conductive pattern 154 (see FIG. 9) is subjected to secondary patterning to form a transparent conductive pattern 150 having a contact hole (CH) through which a portion of the current blocking pattern 140 is exposed. Specifically, the transparent conductive pattern 150 having a contact hole (CH) through which a portion of the current blocking pattern 140 is exposed is formed by photolithography of the transparent conductive layer using a third mask. Upon secondary patterning, some of opposite edges of the preliminary transparent conductive pattern may also be removed.

Some of the current blocking pattern 140 is exposed through the contact hole (CH). Preferably, the contact hole (CH) is formed to expose half or more the area of the current blocking pattern 140 therethrough in order to secure a contact area between the current blocking pattern 140 and a p-electrode pad 160 described hereinafter.

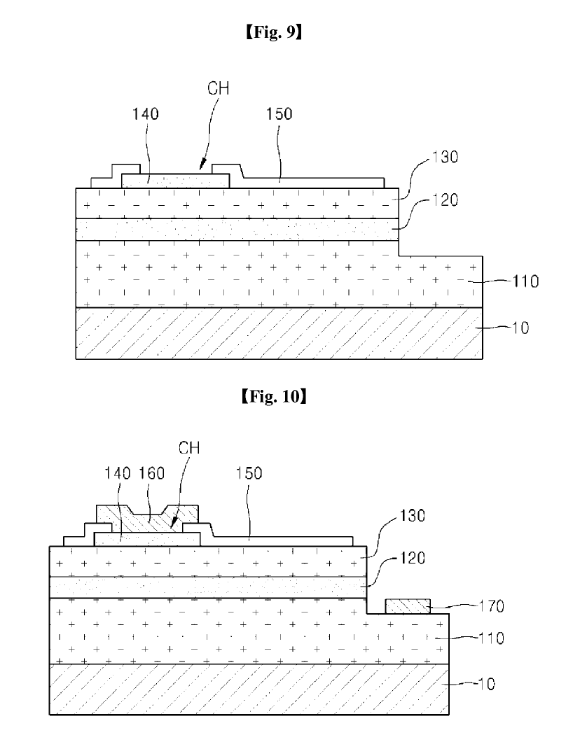

Referring to FIGS. 3 and 10, in operation of forming electrode pads (S160), the p-electrode pad 160 is formed to be directly connected to the current blocking pattern 140, and an n-electrode pad 170 is formed on the exposed portion of the n-type nitride layer 110. The p-electrode pad 160 and the n-electrode pad 170 may be formed by depositing a material selected from among Au, Cr—Au alloys, and the like over upper sides of the p-type nitride layer 130, the transparent conductive pattern 150 having the contact hole and the exposed n-type nitride layer 110 to form a metal layer (not shown), followed by selective patterning through photolithography using a fourth mask.

In plan view, the p-electrode pad 160 may have a first area and the current blocking pattern 140 has a second area larger than or equal to the first area such that the overall area of the p-electrode pad 160 overlaps the current blocking pattern 140. This is because the larger area of the current blocking pattern 140 than that of the p-electrode pad 160 is advantageous in compensation for optical loss due to photon absorption, thereby improving light scattering characteristics.

In the nitride semiconductor light emitting device formed through such a 4-mask process according to the embodiment of the invention, the current blocking pattern is formed on the p-type nitride layer and the transparent conductive pattern having the contact hole is formed on the upper sides of the p-type nitride layer and the current blocking pattern to improve optical scattering characteristics. In addition, the p-electrode pad is electrically and physically directly connected to the current blocking pattern formed of an insulating material through the contact hole of the transparent conductive pattern to improve adhesion of the p-electrode pad, thereby enhancing long-term reliability.

Although the nitride semiconductor light emitting device is described as being formed by sequentially stacking the n-type nitride layer, the active layer, the p-type nitride layer, the current blocking pattern, the transparent conductive pattern, the p-electrode pad and the n-electrode pad in the above embodiments, it should be understood that these embodiments are provided for illustration only and the nitride semiconductor light emitting device according to the present invention may have a structure in which the n-side and the p-side are stacked in reverse sequence.

Although some embodiments have been described herein, it should be understood by those skilled in the art that these embodiments are given by way of illustration only, and that various modifications, variations and alterations can be made without departing from the spirit and scope of the invention. Therefore, the scope of the invention should be limited only by the accompanying claims and equivalents thereof.

What is claimed is:

1. A nitride semiconductor light emitting device comprising:
an n-type nitride layer;
an active layer formed on the n-type nitride layer;
a p-type nitride layer formed on the active layer;
a current blocking pattern formed on the p-type nitride layer;
a transparent conductive pattern formed to cover upper sides of the p-type nitride layer and the current blocking pattern, and having a contact hole through which a portion of the current blocking pattern is exposed; and
a p-electrode pad formed on the current blocking pattern and the transparent conductive pattern to be directly connected to the current blocking pattern.

2. The nitride semiconductor light emitting device according to claim 1, further comprising: an n-electrode pad formed in an exposed area of the n-type nitride layer.

3. The nitride semiconductor light emitting device according to claim 1, wherein the p-electrode pad has a first area and the current blocking pattern has a second area greater than or equal to the first area in plan view.

4. The nitride semiconductor light emitting device according to claim 1, wherein an overall area of the p-electrode pad overlaps the current blocking pattern in plan view.

5. The nitride semiconductor light emitting device according to claim 1, wherein the p-electrode pad has a T-shaped cross-section.

6. The nitride semiconductor light emitting device according to claim 1, wherein the current blocking pattern is formed of at least one selected from SiO₂ and SiNx.

7. The nitride semiconductor light emitting device according to claim 1, wherein the current blocking pattern has a thickness of 0.01 μm to 0.50 μm.

8. The nitride semiconductor light emitting device according to claim 1, wherein the transparent conductive pattern is formed of at least one material selected from among indium tin oxide (ITO), indium zinc oxide (IZO), and fluorine doped tin oxide (SnO₂) (FTO).

9. A method of manufacturing a nitride semiconductor light emitting device, comprising:
sequentially forming an n-type nitride layer, an active layer, and a p-type nitride layer on a substrate;
forming a current blocking pattern on the p-type nitride layer;
forming a transparent conductive layer to cover upper sides of the p-type nitride layer and the current blocking pattern, followed by primary patterning a portion of the transparent conductive layer placed at one edge of the substrate;
mesa-etching the p-type nitride layer, the active layer and the n-type nitride layer exposed at the one edge of the substrate to expose a portion of the n-type nitride layer;
secondary patterning the transparent conductive layer to form a transparent conductive pattern having a contact hole through which a portion of the current blocking pattern is exposed; and
forming a p-electrode pad directly connected to the current blocking pattern, and an n-electrode pad on the exposed portion of the n-type nitride layer.

10. The method according to clam 9, wherein the current blocking pattern is formed of at least one selected from SiO₂ and SiNx.

11. The method according to clam 10, wherein the current blocking pattern has a thickness of 0.01 μm to 0.50 μm.

12. The method according to clam 9, wherein the contact hole is formed to expose half or more the area of the current blocking pattern therethrough.

13. The method according to clam 9, wherein the p-electrode pad has a first area and the current blocking pattern has a second area larger than or equal to the first area, and an overall area of the p-electrode pad overlaps the current blocking pattern.

14. The method according to clam 13, wherein the p-electrode pad has a T-shaped cross-section.
